(19) United States
(12) Patent Application Publication
(10) Pub. No.: US 2006/0209218 A1
(43) Pub. Date: Sep. 21, 2006

(54) Flexible display device for displaying electronic information

(76) Inventors: Cheng-Chung Lee, Chu Tung Jen (TW); Po-Chuan Chen, Hsintien City (TW)

Correspondence Address: RABIN & BERDO, P.C., Suite 500, 1101 14 Street, N.W., Washington, DC, 20005, US

(21) Appl. No.: 11/167,115

(22) Filed: Jun. 28, 2005

(30) Foreign Application Priority Data
Dec. 31, 2004 (TW) 93221508

(51) Int. Cl. G02F 1/13; G06F 1/16; H05K 7/00; H05K 5/00

(52) U.S. Cl. 349/1; 361/681; 345/30

(57) ABSTRACT

A flexible display device for displaying electronic information has a main body, a small screen, a reel mechanism, a scrolling display and a wrist strap. The screen is disposed on the main body for displaying information. The reel mechanism is disposed on the main body. The scrolling display is rolled and hidden in the main body by the reel mechanism for displaying information, wherein the scrolling display is a CLC display or an OLED display. The wrist strap connects with the main body for securing the main body around a wearer. The scrolling display has a screen puller connected to one side thereof for pulling out the scrolling display. The flexible display device is portable, and usable in a fixed state. In addition, the flexible display is not easily to get lost and lessens abrading of the monitor's surface of the scrolling display from usual wear and tear.

### BACKGROUND OF THE INVENTION

1. Field of the Invention

The present invention relates to a flexible display device for displaying electronic information, and particularly relates to a flexible display device having a wrist strap and a scrolling display combined thereon. The flexible display device is portable, and usable in a fixed state, and the flexible display device has many functions integrated therein. In addition, the flexible display is not easily lost and lessens abrading of the monitor's surface of the scrolling display from usual wear and tear.

2. Description of the Related Art

People in the modern world today often carry with them many electronic devices, such as a PDA, a mobile phone, a digital camera and a voice pen for example. However, it is inconvenient for them to carry many electronic devices around, and while such electronic devices can be worn, they are easily lost.

Referring to U.S. Pat. No. 5,931,764, a wearable device with flexible display is disclosed. The wearable device is composed of a plurality of internal components. The wearable device provides a smart card function and a mobile phone function.

Referring to U.S. Pat. No. 6,621,766, a flexible timepiece in multiple environments is disclosed. The flexible timepiece provides an electrophoresis display that is used in a watch, allowing for a dynamic range of new shapes and environments of use. The flexibility of the display also allows for the novel placement of the watch display. For example, the display can be placed on a shoe, allowing a runner to see the time without having to move their arm into a viewing position. The watch display could also be placed into a wallet, or on a purse or belt.

Referring to U.S. Pat. No. 6,728,166, an electronic device for generating and displaying an item of information that relates a flexible wristwatch is disclosed.

Referring to U.S. Pat. No. 5,818,165, a flexible FED (Field Emission Device) display is disclosed.

However, the prior art only discloses simple time display in the above U.S. patents.

### SUMMARY OF THE INVENTION

The present invention provides a flexible display device that can be worn on the wrist of human or a different object similar in shape to that if the human wrist. The flexible display device has many functions integrated therein. In addition, the flexible display is not easily lost and lessens abrading of the monitor's surface of the scrolling display from usual wear and tear.

One aspect of the invention is a flexible display device for displaying electronic information. The flexible display device comprises a main body, a screen, a reel mechanism, a scrolling display and a wrist strap. The screen is disposed on the main body for displaying information. The reel mechanism is disposed on the main body. The scrolling display is rolled and hidden in the main body by the reel mechanism for displaying information, wherein the scrolling display is a cholesteric liquid crystal (CLC) display. The wrist strap connects with the main body for securing the main body around the wearer.

Another aspect of the invention is a flexible display device for displaying electronic information. The flexible display device comprises a main body, a screen, a reel mechanism, a scrolling display and a wrist strap. The screen is disposed on the main body for displaying information. The reel mechanism is disposed on the main body. The scrolling display is rolled and hidden in the main body by the reel mechanism for displaying information, wherein the scrolling display is an organic light-emitting diode (OLED) display. The wrist strap connects with the main body for securing the main body around the wearer.

The wrist strap connects with the main body to form a ring structure suitable for wearing around the wrist of a user or a similar shaped object. Moreover, the flexible display device can be placed flatly on a desk to become a table display.

The flexible display device can be worn around a wrist or assembled around a similar shaped object, such as the handlebars of a motorcycle or a bicycle. In addition, the flexible display is not easily lost and lessens abrading of the monitor's surface of the scrolling display from usual wear and tear.

The image acquisition unit and the input unit can used to display and input information into the flexible display device. Moreover, the present invention can be used during day or night, and has a recording function, a photograph function, a picture function, a wireless function and a GPS function.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objectives and advantages of the present invention will be more readily understood from the following detailed description when read in conjunction with the appended drawing, in which:

FIG. 1 is a perspective view according to the first embodiment of the present invention;

FIG. 2 is another perspective view according to the first embodiment of the present invention;

FIG. 3 is a perspective view of when a large screen is pulled out according to the first embodiment of the present invention;

FIG. 4 is a perspective view of when a large screen is pulled out according to the second embodiment of the present invention;

FIG. 5 is a perspective view of when a large screen is pulled out according to the third embodiment of the present invention;

FIG. 6 is a perspective view according to the fourth embodiment of the present invention;

FIG. 7 is a perspective view of when a large screen is pulled out according to the fourth embodiment of the present invention; and

FIG. 8 is another perspective view of when a large screen is pulled out according to the fourth embodiment of the present invention.

### DETAILED DESCRIPTION OF PREFERRED EMBODIMENTS

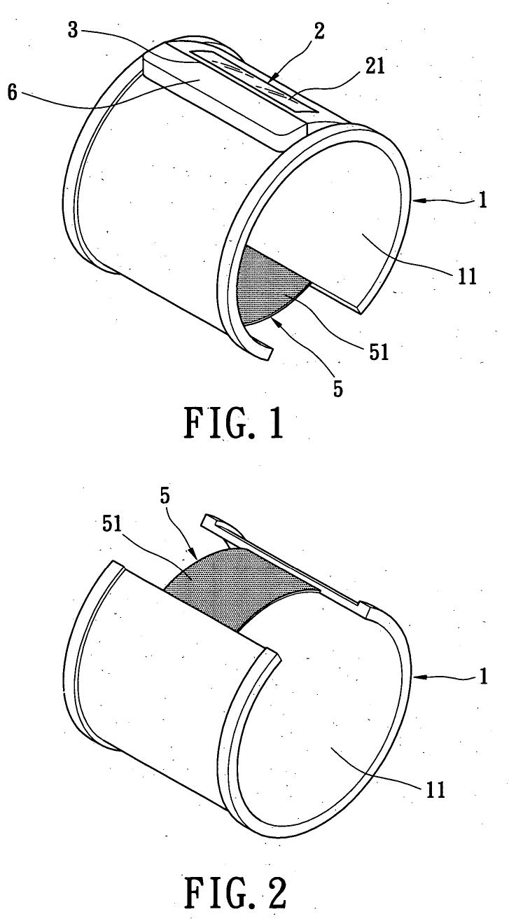

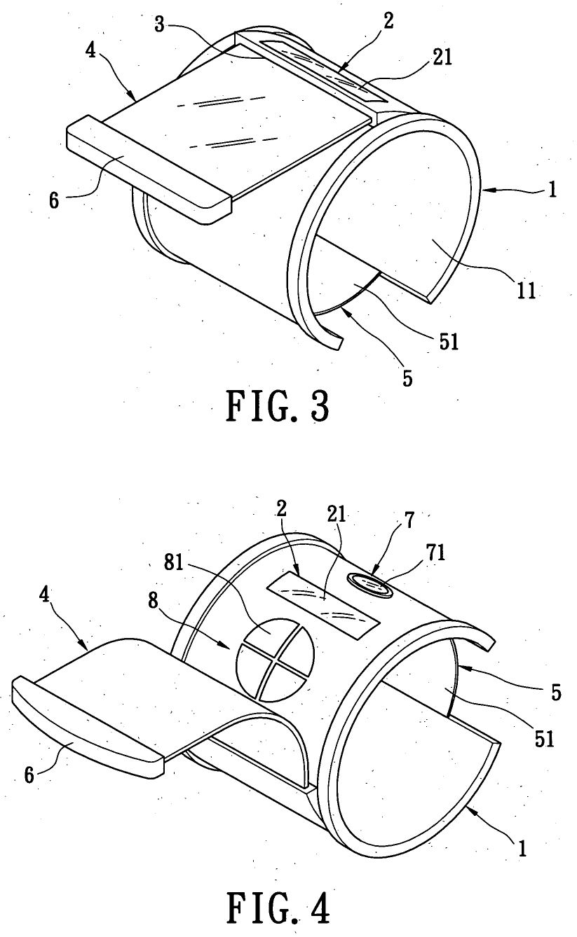

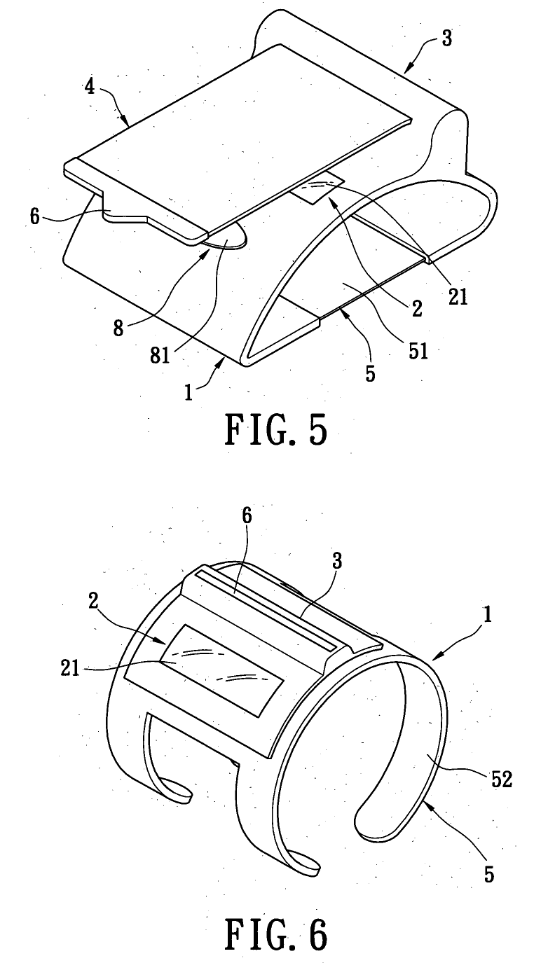

Referring to FIGS. 1 to 3, the present invention provides a flexible display device for displaying electronic information. The flexible display device includes a main body 1, a small screen 2, a reel mechanism 3, a scrolling display (large screen) 4 and a wrist strap 5. The main body 1 is made of flexible or hard material. The main body 1 can be sheet shaped or any other suitable shape. If the main body 1 is made of a hard material, the main body 1 can be curved and a sheet shaped for wearing around a wrist or assembled around a similar shaped object, such as the handlebars of a motorcycle or a bicycle for example. The main body 1 can used to receive the small screen 2, the reel mechanism 3 and the scrolling display 4 therein. The main body 1 has a gel 11 disposed in an inner face thereof for securing the device around the wrist of the user.

The small screen 2 is a flexible screen 21. The flexible screen 21 is disposed on the main body 1. A display medium such as a cholesteric liquid crystal (CLC) or an organic light-emitting diode (OLED), and transistors are disposed on a flexible panel or a PCB to form the flexible screen 21. However the above technology does not limit the present invention. The small screen 2 can also be a hard screen that is used to display simple information, such as the time.

The reel mechanism 3 is disposed on the main body 1. The scrolling display 4 is rolled and hidden in the main body 1 by the reel mechanism 3. A screen puller 6 connects with the scrolling display 4 for easily pulling out the scrolling display 4. The scrolling display 4 is a high-level image display that can display high DPI information. The design of the scrolling display 4 is dual display that can be used to display during either daytime or nighttime. Daytime use is according to a self-luminous display technology, such as CLC. Nighttime use is according to non-self-luminous display technology, such as OLED. The dual display has two panels arranged side-by-side or back-to-back. A display medium and transistors are set on a flexible panel or a PCB to form the flexible scrolling display.

The flexible display device can be fixed onto a wrist by the wrist strap 5. The wrist strap 5 can be a two-piece structure. The two-piece structure has two pieces connected to two opposite sides of the main body 1, respectively. Then the two pieces can be jointed together by an attaching or retaining method. The wrist strap 5 can be made of elastic material. The wrist strap 5 connects with the main body 1 to form a ring structure for wearing around the wrist of the user or a similar shaped object. Moreover, the flexible display device can be placed flatly on the desk to act as a table display.

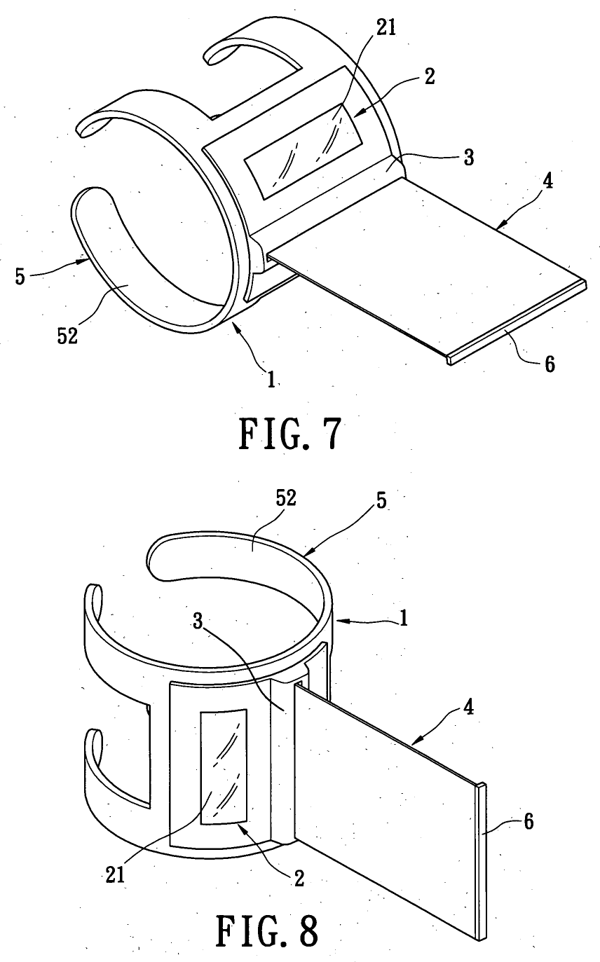

Referring to FIGS. 7 and 8, the flexible display device further includes an image acquisition unit 7 and an input unit 8 according to the demands of the user. The main body 1, the small screen 2, the reel mechanism 3, the scrolling display 4 and the wrist strap 5 each have a different shape. The image acquisition unit 7 can be used to take a picture or photograph. The image acquisition unit 7 can be fixed onto the main body 1, or adjustably assembled on the main body 1 by a movable mechanism (not shown). The image acquisition unit 7 has a lens 71 that can used to adjust the shooting angle. An image sensor, such as a CCD or a CMOS is assembled on a rear side of the image acquisition unit 7 for receiving image light through the lens 71.

The input unit 8 is used to input information into the flexible display device. In the present embodiment, the input unit 8 can be buttons 81 or a touch screen. The buttons 81 can be a power key, a capture/photograph key, a record key, a forward/next key, a backward/previous key, a play/pause key, a stop key, a number/letter key and/or an urgent key. However, the type and number of the buttons 81 are not limiting of the present invention.

Pushing the power key starts the flexible display device. Pushing the picture/photograph key takes a picture or a photograph. The flexible display device has a recorder disposed thereon. Hence pressing the record key can turn on the recording function. In addition, the main body 1 has a microphone and a speaker disposed thereon. Moreover, the main body 1 has a power indicator light for indicating that the power is turned on or off, a photograph indicator light for indicating that the photograph function is turned on or off, a record indicator light for indicating that the recorder is turned on or off, and/or a low power indicator light for indicating whether there is enough power or not. Furthermore, the main body has a GPS disposed thereon.

Referring to FIGS. 6 to 8, the wrist strap 5 is a support 52 in the present embodiment. The support 52 is made of plastic material and is adjustable so that it can become any shape, such as a ring type that can be used on a wrist or a support type that can be used on a desk.

The flexible display device can be worn around a wrist or assembled around a similar shaped object, such as the handlebars of a motorcycle or a bicycle. In addition, the flexible display is not easily lost and lessens abrading of the monitor's surface of the scrolling display from usual wear and tear.

The image acquisition unit 7 and the input unit 8 can be used to display information and input information into the flexible display device. Moreover, the present invention can be used in daytime or nighttime, and has a recording function, a photograph function, a picture function, a wireless function and a GPS function for example.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A flexible display device for displaying electronic information, comprising:
a main body;
a screen disposed on the main body for displaying information;
a reel mechanism disposed on the main body;
a scrolling display rolled and hidden in the main body by the reel mechanism for displaying information, wherein the scrolling display is a cholesteric liquid crystal (CLC) display; and
a wrist strap connecting with the main body for securing the main body around a wearer.

2. The flexible display device as claimed in claim 1, wherein the main body is made of flexible material.

3. The flexible display device as claimed in claim 1, wherein the main body is made of hard material.

4. The flexible display device as claimed in claim 1, wherein the main body has a gel disposed in an inner face thereof.

5. The flexible display device as claimed in claim 1, wherein the screen has at least one flexible screen.

6. The flexible display device as claimed in claim 5, wherein the flexible screen is made by setting a display medium and transistors on a flexible panel or a PCB.

7. The flexible display device as claimed in claim 6, wherein the display medium is cholesteric liquid crystal (CLC).

8. The flexible display device as claimed in claim 6, wherein the display medium is an organic light-emitting diode (OLED).

9. The flexible display device as claimed in claim 1, wherein the scrolling display has a screen puller connected to one side thereof.

10. The flexible display device as claimed in claim 1, wherein the scrolling display is a dual display that is used to display in the daytime or the nighttime.

11. The flexible display device as claimed in claim 10, wherein the dual display has two panels arranged side-by-side.

12. The flexible display device as claimed in claim 10, wherein the dual display has two panels arranged back-to-back.

13. The flexible display device as claimed in claim 1, wherein the scrolling display is made by setting a display medium and transistors on a flexible panel or a PCB.

14. The flexible display device as claimed in claim 13, wherein the display medium is cholesteric liquid crystal (CLC).

15. The flexible display device as claimed in claim 1, wherein the scrolling display is a high-level image display.

16. The flexible display device as claimed in claim 1, wherein the wrist strap is a two-piece structure.

17. The flexible display device as claimed in claim 1, wherein the wrist strap is made of elastic material.

18. The flexible display device as claimed in claim 1, wherein the wrist strap is a support.

19. The flexible display device as claimed in claim 1, further comprising an image acquisition unit disposed on the main body for taking pictures or photographs.

20. The flexible display device as claimed in claim 1, further comprising an input unit disposed on the main body for inputting information.

21. The flexible display device as claimed in claim 20, wherein the input unit is buttons.

22. The flexible display device as claimed in claim 20, wherein the input unit is a touch screen.

23. The flexible display device as claimed in claim 20, wherein the input unit has a power key, a capture/photograph key, a record key, a forward/next key, a backward/previous key, a play/pause key, a stop key, a number/letter key and/or an urgent key.

24. The flexible display device as claimed in claim 1, wherein the main body has a recorder disposed thereon.

25. The flexible display device as claimed in claim 1, wherein the main body has a microphone and a speaker disposed thereon.

26. The flexible display device as claimed in claim 1, wherein the main body has a power indicator light, a photograph indicator light, a record indicator light and/or a low power indicator light.

27. The flexible display device as claimed in claim 1, wherein the main body has a GPS disposed thereon.

28. A flexible display device for electronic information, comprising:
a main body;
a screen disposed on the main body for displaying information;
a reel mechanism disposed on the main body;
a scrolling display rolled and hidden in the main body by the reel mechanism for displaying information, wherein the scrolling display is an organic light-emitting diode (OLED) display; and
a wrist strap connecting with the main body for securing the main body around a wearer.

29. The flexible display device as claimed in claim 28, wherein the main body is made of flexible material.

30. The flexible display device as claimed in claim 28, wherein the main body is made of hard material.

31. The flexible display device as claimed in claim 1, wherein the main body has a gel disposed in an inner face thereof.

32. The flexible display device as claimed in claim 1, wherein the screen has at least one flexible screen.

33. The flexible display device as claimed in claim 32, wherein the flexible screen is made by setting a display medium and transistors on a flexible panel or a PCB.

34. The flexible display device as claimed in claim 33, wherein the display medium is cholesteric liquid crystal (CLC).

35. The flexible display device as claimed in claim 33, wherein the display medium is an organic light-emitting diode (OLED).

36. The flexible display device as claimed in claim 28, wherein the scrolling display has a screen puller connected to one side thereof.

37. The flexible display device as claimed in claim 28, wherein the scrolling display is a dual display that is used to display in the daytime or the nighttime.

38. The flexible display device as claimed in claim 37, wherein the dual display has two panels arranged side-by-side.

39. The flexible display device as claimed in claim 37, wherein the dual display has two panels arranged back-to-back.

40. The flexible display device as claimed in claim 28, wherein the scrolling display is made by setting a display medium and transistors on a flexible panel or a PCB.

41. The flexible display device as claimed in claim 40, wherein the display medium is cholesteric liquid crystal (CLC).

42. The flexible display device as claimed in claim 28, wherein the scrolling display is a high-level image display.

43. The flexible display device as claimed in claim 28, wherein the wrist strap is a two-piece structure.

44. The flexible display device as claimed in claim 28, wherein the wrist strap is made of elastic material.

45. The flexible display device as claimed in claim 28, wherein the wrist strap is a support.

46. The flexible display device as claimed in claim 28, further comprising an image acquisition unit disposed on the main body for taking pictures or photographs.

47. The flexible display device as claimed in claim 28, further comprising an input unit disposed on the main body for inputting information.

48. The flexible display device as claimed in claim 47, wherein the input unit is buttons.

49. The flexible display device as claimed in claim 47, wherein the input unit is a touch screen.

50. The flexible display device as claimed in claim 47, wherein the input unit has a power key, a capture/photograph key, a record key, a forward/next key, a backward/previous key, a play/pause key, a stop key, a number/letter key and/or an urgent key.

51. The flexible display device as claimed in claim 28, wherein the main body has a recorder disposed thereon.

52. The flexible display device as claimed in claim 28, wherein the main body has a microphone and a speaker disposed thereon.

53. The flexible display device as claimed in claim 28, wherein the main body has a power indicator light, a photograph indicator light, a record indicator light and/or a low power indicator light.

54. The flexible display device as claimed in claim 28, wherein the main body has a GPS disposed thereon.
